(19) United States
(12) Patent Application Publication
(10) Pub. No.: US 2006/0071819 A1
(43) Pub. Date: Apr. 6, 2006

(54) Transparent touch-sensitive switching system

(76) Inventors: Mark Thomas Johnson, Eindhoven (NL); Dirk Kornelis Gerhardus De Boer, Eindhoven (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/537,388

(22) PCT Filed: Nov. 12, 2003
(86) PCT No.: PCT/IB03/05099

§ 371 Date: Jun. 3, 2005

(30) Foreign Application Priority Data
Dec. 9, 2002 (EP) 02080158.5

(51) Int. Cl. H03M 1/22

(52) U.S. Cl. 341/15

(57) ABSTRACT

The invention pertains to an at least partially transparent touch-sensitive switching system comprising at least two electrodes provided with means for applying a voltage thereto and spaced from each other by a layer comprising at least one region that optically changes by applying the voltage, and at least one region comprising a piezoelectric material generating a voltage when applying pressure thereto.

The invention pertains to an at least partially transparent touch-sensitive switching system and an electro-optical display comprising said touch-sensitive switching system.

A transparent touch-sensitive switching system was disclosed in U.S. Pat. No. 4,516,112. According to this patent a display was made with a display screen. Above the display screen a piezoelectric film was supported for selective localized depression towards the screen. The film has transparent flexible conductive coatings on opposite sides of the piezoelectric film. These transparent flexible conductive coatings are necessary to generate a voltage in response to depression of the film. This system has the disadvantage that production thereof is expensive, since the piezoelectric film must be provided with two extra transparent flexible conductive coatings. Moreover, the addition of these transparent flexible conductive coatings has a disadvantageous effect on the transparency of the display, particularly in displays that operate with low power consumption, such as displays that are in use in mobile systems like mobile telephone displays, notebook computer systems, and the like. Further, these displays are thick and therefore relatively heavy, providing an other disadvantage, particularly in mobile systems.

There is thus a serious need for improvement of the aforementioned system, in respect to manufacturing costs, optical performance (i.e. transparency), weight, and low energy consumption.

The present invention provides an improved at least partially transparent touch-sensitive switching system comprising at least two electrodes provided with means for applying a voltage thereto and spaced from each other by a layer comprising at least one region that optically changes by applying the voltage, and at least one region comprising a piezoelectric material generating a voltage when applying pressure thereto.

The present system can be manufactured at relatively low costs and has excellent optical properties. It should be stressed that the piezoelectric material is preferably a piezoelectric polymer. Such piezoelectric polymer can replace the conventional polymer that is present in almost any electro-optical display. Thus the displays of the invention can be made at about the same costs as conventional displays by simply using a piezoelectric polymer matrix material rather than a normal polymeric matrix material.

Other transparent touch-sensitive switching systems are known, such as disclosed in U.S. Pat. No. 5,159,323 wherein a display is disclosed with a piezoelectric material disposed between two substrates. However, this system is incomparable with the present system in that it makes use of a unique ferroelectric liquid crystalline material that inherently also has piezoelectric properties. Thus this material is used both as light influencing medium and as a pressure sensitive medium. Such system is very restricted in materials than can be used, and consequently very restricted in their applications. In contrast, the present invention provides in a system of a touch-sensitive switching method that can be combined with any material that can give an optical (light) effect, including non-liquid crystalline materials.

The present system allows the manufacture of display cells, which upon touching generates a voltage in the piezoelectric material that serves to detect the touch position. Examples of displays wherein the touch-sensitive system of the invention can be used are PDLC (polymer dispersed liquid crystal), electrophoretic displays, Gyricon™, PDCTLC (polymer dispersed cholesteric texture liquid crystal), polymer dispersed guest/host systems, and other polymer dispersed LC effects, systems with pixel walls (electrochromic, electrowetting, ASM (axial symmetric microcell) mode LCD, and the like). Preferably, the piezoelectric material is a polymer or a polymer comprising piezoelectric particles, which may be applied to make special spacer constructions, such as in a lithographic manner as disclosed by Odahara et al. in SID 01 Digest, p. 1358, or by micro-embossing. It is however, more preferred to incorporate the piezoelectric material in the pixel. In another preferred embodiment a display is made wherein at least one of the conductive or semi-conductive layers is placed onto a substrate. The substrate may be any material that is commonly used for this purpose, such as glass or plastic, among which polycarbonate, polyurethane and the like. In a preferred embodiment according to the invention the touch-sensitive switching system has at least one of the electrodes placed onto a substrate. The touch-sensitive switching system is at least partially transparent. For many applications it is preferred that the system is fully transparent.

The piezoelectric materials are known in the art and commercially available. Most commonly used is polyvinylidene fluoride (PVDF) film, for instance having a thickness of 10 to 100 μm, but it is clear that any other piezoelectric material can also suitably be used, such as a ferroelectric (chiral smectic C*) elastomer (Brahma, M., Wiesemann, A., Zentel, R., Siemensmeyer, K., Wagenblast, G., Polymer Preprints, 1993, 34 (2), 708; bttp://staudinger.chernie.uni-mainz.de/akzentel/Publikationen/p99 1.htm#13), and polymers comprising piezoelectric particles (e.g. a titanate).

When using a piezoelectric polymer, the molecular alignment by applying a high-poling voltage creates the piezoelectric effect. Thus the randomly oriented piezoelectric material is ordered on applying a high-voltage poling voltage. Touch signals may then be measured over the pixel electrodes that are already present to drive the pixels, thus no extra connections are necessary in the display. By identification which row and column has generated a voltage upon applying pressure, sensing can be carried out.

The invention is further illustrated by the following figures.

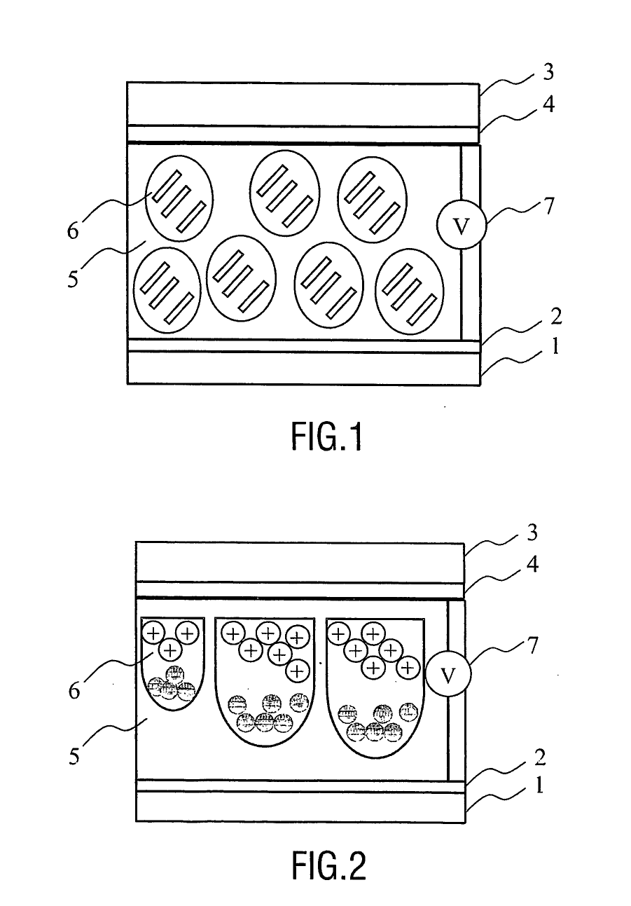

FIG. 1 shows schematically a touch-sensitive pixel according to the invention with a piezoelectric polymer and regions containing liquid crystalline material.

FIG. 2 shows schematically a touch-sensitive pixel according to the invention with a piezoelectric polymer and capsules containing electrostatically charged particles.

In FIG. 1 a first substrate 1 is provided with an ITO layer (conductive layer) 2. A second substrate 3 is also provided an ITO layer 4. The two substrates are spaced apart by a polymer layer 5, having piezoelectric properties, by being piezoelectric as such or by comprising piezoelectric material. In polymer layer 5 regions 6 are present which may be “floating” droplets comprising liquid crystalline (LC) molecules or may be a capsule filled with LC molecules. If a capsule is used such capsule is made of a thin transparent polymeric film that are commonly used for making capsules. The regions that optically change by applying the voltage are embedded in a matrix of the piezoelectric polymer. Means 7 are present for applying a voltage over the ITO layers 2 and 4.

The layer 5 can be exposed to a high electric field in order to align the piezoelectric polymer.

In this way, the entire pixel region is touch-sensitized, which makes this touch-sensitive approach applicable for flexible and even wearable display applications.

According to this embodiment the touch signal over the pixel electrodes is measured by the connections already present to drive the pixels. Sensing is carried out by simply identifying the row and column that have generated a voltage as a result of the touch pressure.

There method can be used for a wide range of liquid crystal systems that rely on a polymer network to create the desired electro-optical properties. Examples are PDLC, PDCTLC, guest-host systems with polymer networks (as used in camera shutter systems), etc. Each pixel may contain a plurality of regions 6, but more preferably each region 6 is an individual pixel.

An embodiment of an LCD with polymer network where pixels are individually encapsulated using a polymer network is the so-called Axially Symmetric Mode (ASM) used for wide viewing angle LCD's and PALC (plasma addressed liquid crystal) displays.

In FIG. 2 a glass substrate 1 is provided with an ITO layer (conductive layer) 2. A second substrate 3 is a PET layer with a thickness of 175-250 μm, which is also provided with an ITO layer 4. The two substrates are spaced apart by a polymer layer 5, having piezoelectric properties, by being piezoelectric as such or by comprising piezoelectric material. In polymer layer 5 capsules 6 are present filled with electrostatically charged particles, wherein the particles are dispersed in a fluid (gas or liquid). Means 7 are present for applying a voltage over the ITO layers 2 and 4. Again each pixel may contain a plurality of capsules, but more preferably each capsule represents an individual pixel. In this figure is indicated that the electrostatically charged particles are two different sorts of particles, whereof the colors are in contrast to each other and which are dispersed in a colorless fluid. In this particular case the capsules contain black and white particles in a colorless fluid, for instance negative electrostatically charged carbon black particles and positive electrostatically charged white TiO₂ particles. Alternatively, the particles can also be electrostatically charged particles having only one color that is in contrast to the color of the fluid.

In this case, the piezoelectric polymer will be used as binder. The principle of the present invention may advantageously also be used in many other types of electrophoretic display concepts that have been proposed in patent applications. These concepts will also function better if pixels are individually encapsulated using a polymer network. Again, this polymer network could be made piezoelectric to enable touch sensing. For instance, the known display principle called Gyricon™ (ex Xerox) could be made intrinsically touch-sensitive. Here, the polymer network forming the binder around the rotating balls with black and white hemispheres could be made piezoelectric to enable touch sensing.

In another embodiment according to the invention (not shown) two electrodes are placed on the same substrate and spaced from each other by a layer 5 containing regions 6, according to layer 5 and regions 6 of FIGS. 1 or 2. These electrodes may alternatively also be contained in the same layer 5. The system of the invention may further contain one or more of the usual other layers, such as substrate layers, intermediate layers, compensation or retardation layers, polarization layers, protective layers, and the like.

Several concepts for electrochromic and electrowetting display pixels will function better if pixels are individually encapsulated using a polymer network. Here also, this polymer network could be made piezoelectric to enable touch sensing.

1. An at least partially transparent touch-sensitive switching system comprising at least two electrodes provided with means for applying a voltage thereto and spaced from each other by a layer comprising at least one region that optically changes by applying the voltage, and at least one region comprising a piezoelectric material generating a voltage when applying pressure thereto.

2. The touch-sensitive switching system of claim 1 wherein at least one of the electrodes is transparent.

3. The touch-sensitive switching system of claim 1 wherein the piezoelectric material is a piezoelectric polymer.

4. The touch-sensitive switching system of claim 1 wherein the regions that optically change by applying the voltage are regions comprising a fluid or a dispersion of particles in a fluid.

5. The touch-sensitive switching system of claim 4 wherein the fluid comprises liquid crystalline molecules.

6. The touch-sensitive switching system of claim 4 wherein the particles are electrostatically charged.

7. The touch-sensitive switching system of claim 6 wherein the electrostatically charged particles have a color that is in contrast to the color of the fluid, or wherein the particles are dispersed in a colorless fluid and the dispersion comprises at least two different sorts of electrostatically charged particles, whereof the colors are in contrast to each other.

8. The touch-sensitive switching system of claim 1 wherein the regions that optically change by applying the voltage are embedded in a matrix of the piezoelectric material.

9. The touch-sensitive switching system of claim 6 wherein the dispersion of electrostatically charged particles in a fluid is enclosed in a capsule of a polymeric material.

10. An electro-optical display comprising the touch-sensitive switching system of claim 1.

11. The display of claim 10 wherein each region that optically changes by applying the voltage corresponds to one pixel, and wherein each pixel is a pressure-sensitive pixel.
